(19) United States
(12) Patent Application Publication
(10) Pub. No.: US 2026/0328821 A1
(43) Pub. Date: Oct. 22, 2026

(54) RADIO FREQUENCY (RF) TESTING, MEASUREMENT, AND MAINTENANCE DEVICE

(71) Applicant: VIAVI SOLUTIONS INC., Chandler, AZ (US)

(72) Inventors: Bon-Jin KU, Seoul (KR); Seong-Mann JOE, Incheon (KR); Seung-Gon HONG, Seoul (KR)

(73) Assignee: VIAVI SOLUTIONS INC., Chandler, AZ (US)

(21) Appl. No.: 19/184,405

(22) Filed: Apr. 21, 2025

(51) Int. Cl. G01R 29/08; H04B 17/345; H01Q 1/24; H01Q 21/06

(52) U.S. Cl. CPC G01R 29/0878; G01R 29/0871; G01R 29/0892; H04B 17/345; H01Q 1/241; H01Q 21/06

(57) ABSTRACT

A testing device provides for testing conditions with radio frequency (RF) interference. The testing device includes a processor, a memory to store machine readable instructions executable by the processor to perform data center testing, an input/output device comprising a camera, a display, a phased array antenna (PAA), and an RF control component, wherein the RF control component is to focus reception of the PAA according to analyzed RF interference and adjust a viewing of the camera synchronously with focusing reception of the PAA.

### TECHNICAL FIELD

This patent application relates generally to testing of communication networks, and more specifically, to finding radio frequency interference via implementation of a phased array antenna.

### BACKGROUND

Data centers are centralized computer network systems that enable transfer of data and content (e.g., over the internet), and provide storage and backup of the data and content as well. This may include transfer between two data centers a few miles apart, or two data centers connected via trans-oceanic links.

A data center often includes various communications equipment to support network communications. This equipment typically connects to wireline communications networks, which may be comprised of fiber optic cables and coaxial cables.

Typically, finding interference in a radio frequency (RF) environment may involve use of a testing device. In addition to other signal analysis features (e.g., spectrum analysis, etc.), the testing device may provide interference finding by analyzing aspects of RF power.

However, analyzing RF power to determine RF interference may, in some instances, come with difficulties. In particular, in many instances, identifying and analyzing RF interference may be a time-consuming process that may be difficult for on-site technicians to accomplish. For example, an on-site technician operating a testing device may not necessarily be able to make adjustments to home in (i.e., focus) on to the RF interference and to troubleshoot when issues may arise.

### BRIEF DESCRIPTION OF THE DRAWINGS

Features of the present disclosure are illustrated by way of examples shown in the following figures. In the following figures, like numerals indicate like elements, in which:

FIG. 1A illustrates a perspective view of a testing device including a base module and an input/output (I/O) device, according to an example of the present disclosure;

FIG. 1B illustrates a back side view of a base module, according to an example of the present disclosure;

FIG. 1C illustrates a top view of a base module, according to an example of the present disclosure;

FIG. 1D illustrates a bottom view of a base module, according to an example of the present disclosure;

FIG. 1E illustrates an exploded perspective view of a testing device including an I/O device, a base module, and dual expansion modules, according to an example of the present disclosure;

FIG. 1F illustrates an exploded perspective view of a testing device including a removably connected module, according to an example of the present disclosure;

FIG. 2 illustrates a test process automation workflow, according to an example of the present disclosure;

FIG. 3A illustrates a high level system diagram of test process automation, according to an example of the present disclosure;

FIG. 3B illustrates a graphical user interface (GUI) for a testing device having an automated test plan, according to an example of the present disclosure;

FIG. 4A illustrates a system diagram of a testing device connected to a workstation by an Ethernet connection for remote access and control, according to an example of the present disclosure;

FIG. 4B illustrates a system diagram of a testing device connected to a workstation by a wireless network connection for remote access and control, according to an example of the present disclosure;

FIG. 5 illustrates a RF interference finder, according to examples of the present disclosure;

FIGS. 6A-6B illustrate testing apparatuses with RF interference capabilities, according to examples of the present disclosure;

FIG. 7 illustrates a plurality of charts indicating RF interference for a PAA, according to examples of the present disclosure;

FIG. 8 illustrates a plurality of charts indicating RF interference for a PAA, according to examples of the present disclosure;

FIGS. 9A-9B illustrate images provided by a camera of an RF interference finder, according to examples of the present disclosure; and

FIG. 10 illustrates a method for determining RF interference utilizing a PAA, according to examples of the present disclosure.

### DETAILED DESCRIPTION

For simplicity and illustrative purposes, the present disclosure is described by referring mainly to examples thereof. In the following description, details are set forth in order to provide an understanding of the present disclosure. It will be readily apparent however, that the present disclosure may be practiced without limitation to these details. In other instances, some methods and structures have not been described in detail so as not to unnecessarily obscure the present disclosure.

Throughout the present disclosure, the terms “a” and “an” are intended to de at least one of a particular element. As used herein, the term “includes” means includes but not limited to, the term “including” means including but not limited to. The term “based on” means based at least in part on.

Data centers enable sharing of data and content and provide storage and backup for redundancy, and typically house compute and storage resources for applications, data, and content. A data center typically includes various electronic equipment to support network communication(s).

The electronic equipment of a data center generally connects to wireline networks, which may be comprised of fiber optic cables and coaxial cables. The sharing may take place between two data centers a few miles apart, or two data centers connected via trans-oceanic lines.

One technology that may be utilized to enable sharing across data centers is Data Center Interconnection (DCI) technology. DCI may be utilized to implement high-speed data packet transfer for two or more data centers over various distances.

It may be appreciated that data center operations may depend on a wide range of design and logistical variables. Examples of these variables may include, among others, a location of the data center(s), distance between data centers, bandwidth, cost, and capacities of local service providers.

In some instances, a bandwidth of a data center may be expressed as a data rate. Typical data rates may range from, for example, ten (10) gigabits per second (also referred to as “10G”) to eight hundred (800) gigabits per second (also referred as “800G”). Presently, many data centers are migrating from implementation of 400G (i.e., four-hundred (400) gigabits per second) data rates to implementation of 800G data rates, particularly for communication ”links” extending from a first data center to a second data center.

Another variable in data center configuration may be cable types that may be used to connect various network devices. These cables are typically pre-assembled with predetermined form factors, and typically enable “plug and play” implementation. Moreover, these cables may be accommodate various data rates, may be “active” or “passive,” and may be “split” (i.e., a 400G cable may be split into two 200G cables).

A first example of a cable type may be a direct attach copper (DAC) cable. DAC cables are copper cables with transmission modules (i.e., connectors) that enable the DAC cable to connect directly into a port of a network device (e.g., a switch, router, server, or data storage device). A second example of a cable type may be active optical cable (AOC). AOC cables are a fiber optic cables that typically employ electrical-to-optical conversion to connect to standard electrical interfaces.

Yet another variable in data center configuration is the connector type used to connect a network cable to a network device. Typically, a module of the connector is connected to a device, where the connector is placed inside of a housing element (or “cage”), which guides the module into a connector element of the device. For example, in some instances, certain data center devices may utilize an Octal Small Form Factor Pluggable (OSFP) connector. An OSFP connector may, for example, typically accommodate up to a 400G data rate. In other instances the data center devices may utilize an Octal Small Form Factor Pluggable (QSFP) connector. The QSFP connector may, for example, often accommodate up to a 800G data rate (e.g., QSFP-DD, QSFP+, etc.).

With all these variables at play, it may be appreciated that testing of data center operations, including devices and configurations, may come with a number of significant complexities. These complexities may relate to device installation and optimization, preventative and remedial maintenance, integration of network hardware and interconnect elements, maintaining and repairing data center equipment, testing and analyzing network communication, and testing network integrity and quality. For example, data center testing may be directed to testing aspects of connections between data centers (i.e., “link testing”), or may be directed to testing aspects of connection between testing devices (e.g., cable testing). Furthermore, testing may be required prior to installation or during operation. In addition, data center testing may include a myriad of particular tests, such as bit-error rate (BER) testing, forward error correction (FEC) testing, etc.

In some instances, a typical testing scenario may often require use of two testing devices. Specifically, in some instances, a testing device (e.g., a handheld device) may include only one port having one connector type (e.g., either QSFP or OSFP connector). For example, this may not enable testing associated with two different connector types, or otherwise may require use of an adapter. In such instances where two data center devices may be required, a first testing device may be implemented to run a test script, while the second tester is typically employed to monitor through and received (i.e., “loopback”) communications.

In some instances, these complexities may require the expertise of one or more on-site engineers. However, this may significantly increase operational costs of a data center. With proper equipment and training, data centers may instead be serviced by a technician, and thereby reducing a need for an on-site engineer. With proper equipment, a technician may be able to troubleshoot and optimize a large number of the issues that may arise during data center operations.

A data center installation, testing, measurement, and maintenance device, referred to herein as a testing device or testing device, provides a configurable, multi-protocol testing system for telecommunication systems. For example, the testing device described herein provides field technicians with resources to support multiple aspects of data center testing, including testing for installation and maintenance of data centers, and testing related to, and not limited to, network devices, fiber optic cables and optical signals, coaxial cables and antennas.

The testing device as described provides multiple technical advantages over existing devices. The testing device delivers improved efficiencies as it may replace multiple independent devices that may typically be required for testing scenarios, and provide additional measurements and insights that can improve installation and maintenance of data centers.

As described in further detail below, the testing device is modular, in that different modules may be added to the testing device to facilitate different types of testing. A module may be, among other things, a software or hardware element, or a combination of hardware and software elements that may be utilized in conjunction with the testing device (as further described below). Thus, the testing device is scalable, because modules can be added to the testing device to accommodate new testing requirements and scenarios. In addition, the testing device may be mounted on a variety of data center devices, such as a server rack (i.e., it may be “rack-mountable”).

Also, as described in further detail below, the testing device may include job manager software that enables automated testing to be performed. A job may comprise one or more tests to be performed by the testing device in a specified sequence. One or more jobs may be created and stored in the testing device for different tasks. Jobs, including workflows for testing, can be defined centrally and downloaded to testing devices at multiple data centers, eliminating the variability of manual procedures and thereby driving consistent, repeatable results, regardless of technician skill or experience level.

The testing device permits data center technicians to test, among other things, fiber, radio frequency (RF), Spectrum Analysis (SA), Common Public Radio Interface (CPRI), and Ethernet from a single instrument, replacing multiple independent devices. Examples of other tests the testing device may perform include system development, Ethernet traffic load, transponder hardware validation, BER testing, FEC compliance and validation, and interconnect (IC) development and validation. In an example, and as will be described in further detail below, the testing device includes modules that provide the ability to test specific protocols all in one device.

By implementing use of a testing device as described, training for technicians shifts to learning of the test process itself, which is faster and easier to learn, rather than on analysis of technical information, which is generally time-consuming and overwhelming for new technicians. Furthermore, the job manager software can eliminate wasted technician time regarding trying to remember which tests to run and how to run them. The above-described technical advantages and other technical advantages are further described below.

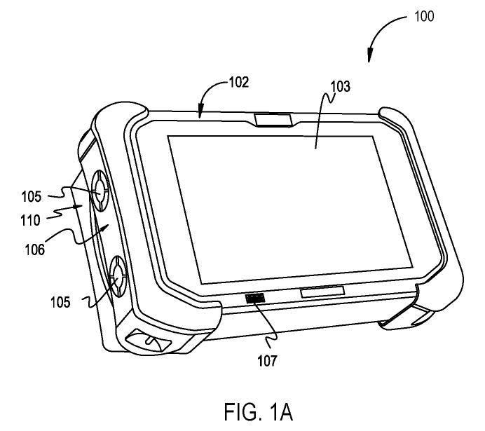

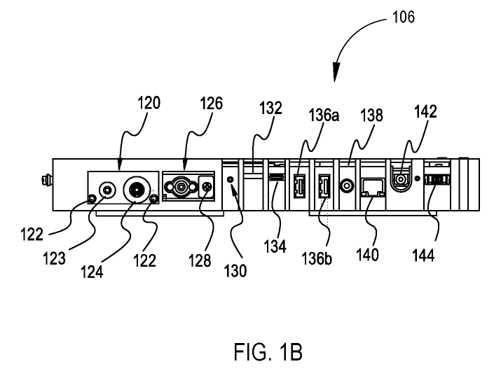

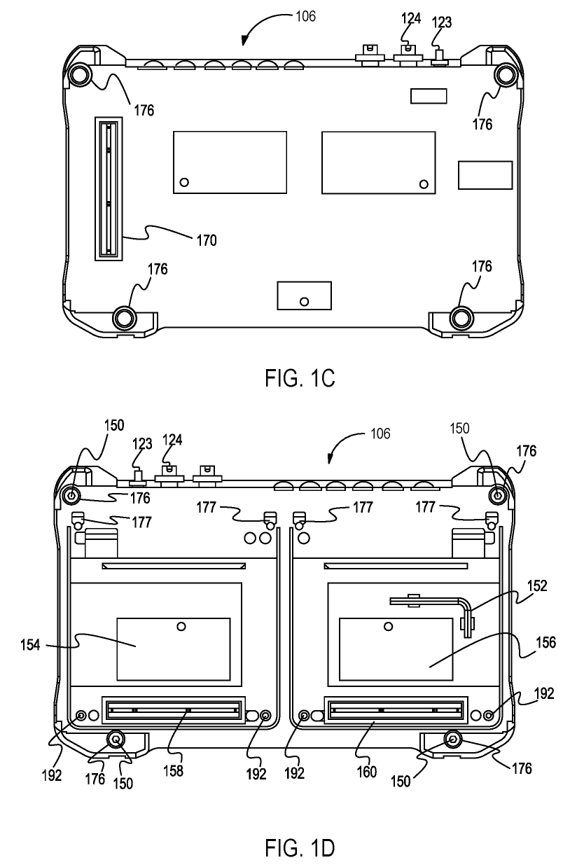

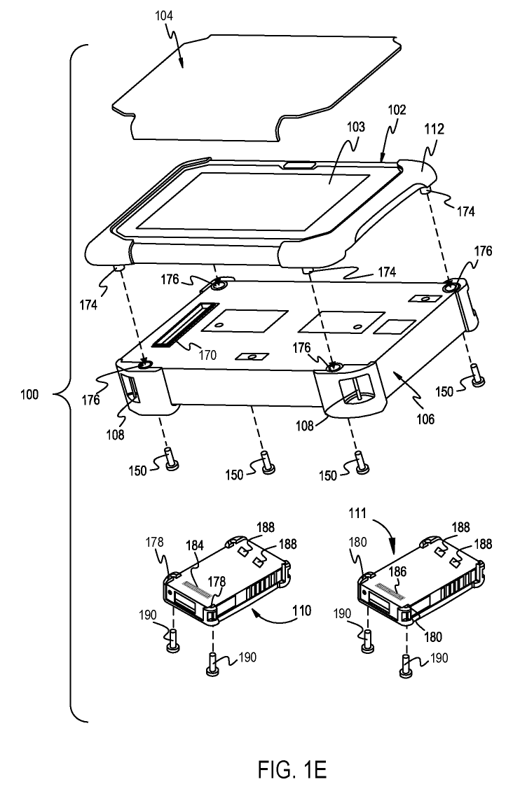

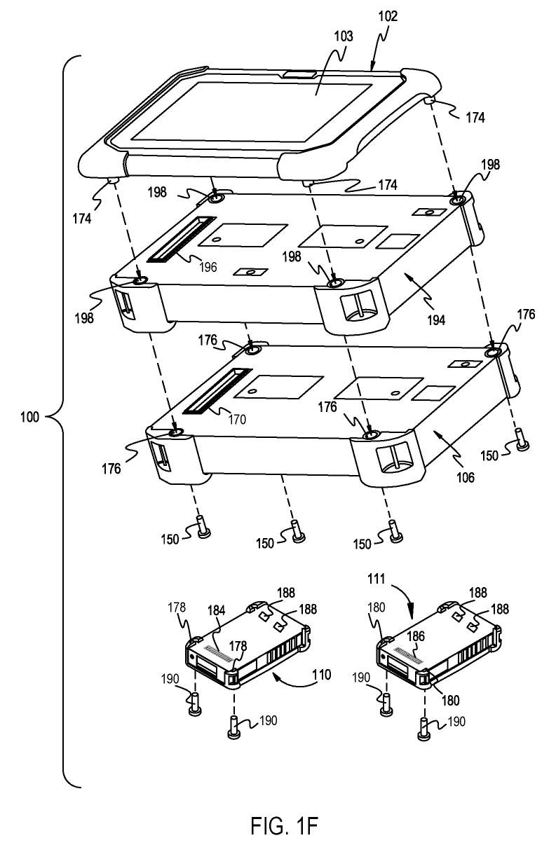

FIG. 1A illustrates a perspective view of a (modular) testing device 100 including base module 106 and I/O device 102 (which may be removably connected), according to an example of the present disclosure. Testing device 100 may be a modular hand-held device comprising removably connectable field replaceable modules for data center installation, testing, measurement, and maintenance. According to an example, testing device 100 includes removably connectable I/O device 102, and a removably connectable base module 106.

According to an example, I/O device 102 includes a display 103 that provides user control and information. According to an example, the display 103 may be a touch screen, e.g., liquid crystal display (LCD) touchscreen. The testing device 100 provides user information including: a listing of jobs, a listing of reports to be compiled, a compilation of executed test results in a test report or test reports, and an interface control with a work station or server. Base module 106 provides hardware, software and firmware to control the testing device 100.

According to the illustrated example of FIG. 1A, ventilation ports 105 are provided to the outer structure of base module 106 to facilitate internal cooling of components by way of an internal cooling unit. Loudspeaker 107 provides audio information. Base module 106 provides a structural base for testing device 100.

According to an example, testing device 100 may be configured in a variety of assemblies with a plurality of different removably connectable modules to support workflow and project specifications. According to the illustrated example of FIG. 1A, testing device 100 includes first expansion module 110 removably connected to the bottom of base module 106.

FIG. 1B illustrates a back side view of base module 106, according to an example. Base module 106, similar to other modules described herein, includes a plurality of modular elements used for data center installation, testing, measurement, and maintenance.

According to an example, base module 106 includes PM-DL module 120, also known as a power meter/datalink optical module. PM-DL module 120 and other modules described herein may be factory installed with base module 106 or one or more modules may be attached to base module 106 by a user. In an example, PM-DL module 120 is secured by way of connection members 122. PM-DL module 120 includes power meter port 123 and TS-PC port 124, also known as a Talkset-Datalink port. Power meter port 123 is used to determine optical power of a fiber under test. TS-PC port 124 is used to communicate voice or data with another device along an optical fiber.

According to an example, base module 106 also includes VFL module 126, also known as a Visual Fault Locator (VFL) module, to provide detection of a visual fault location. A VFL test uses brightly visible light to check patch cords for defects and verify continuity.

According to an example, base module 106 includes a number of additional inputs and control interfaces as follows. Reset button 130 provides a hard reset of testing device 100. Reset button 130 may be depressed with a small object, such as an extended paperclip. Micro-SD port 132 provides removable storage to testing device 100 by accepting a micro-SD card. The micro-SD card may provide memory for storing data center data, predetermined setup configurations, test results, and compiled reports. USB-C port 134 provides an interface to testing device 100 according to the USB-C standard. USB-C port 134 also provides a debug-serial-port to support testing and trouble-shooting of testing device 100. An audio interface, and/or headset may be multiplexed with USB-C port 134 by way of an external adapter, such as a USB-C or 3mm adapter. A pair of USB-A Interfaces 136a and 136b provides support for connection of USB 2.0/3.0 peripherals, such as an external fiber microscope, set forth in greater detail below.

Audio jack 138 provides a direct audio interface by accepting a 3mm male plug. Ethernet port 140 is RJ-45 jack to provide 10/100/1000-BaseT Ethernet management. On/Off switch 142 is configured to turn testing device 100 on and off. DC-input 144 is configured to receive DC power for testing device 100 from an external power supply. Although not illustrated in FIG. 1B, a mini USB port may also be provided. Base module 106 may also include a wireless network module to support wireless network communication and a Bluetooth module to support Bluetooth communication with an external device, such as a Bluetooth audio headset.

FIG. 1C illustrates a top view of base module 106, according to an example of the present disclosure. Base module 106 includes a plurality of through holes 176 to mate with corresponding protrusions 174 in the housing of I/O device 102. Base module 106 provides electrical power and communication to I/O device 102 or other modules, including solution modules and expansion modules, by way of base module backplane interface 170.

FIG. 1D illustrates a bottom view of base module 106, according to an example of the present disclosure. Base module 106 includes a plurality of through holes 176 to receive a plurality of connection members 150 to removably secure base module 106 to I/O device 102. According to an example, connection device 152 is disposed within base module 106 to support field replacement of different removably connectable modules (attachable to a top side of base module 106). Base module 106 includes a plurality of access panels, such as access panels 154 and 156 to support factory installation of various internal modules, such as the wireless network module or Bluetooth module.

Base module 106 includes first expansion interface 158 and second expansion interface 160 to provide electrical communication and power to a plurality of different expansion modules. According to an example, the bottom of base module 106 includes recesses to receive corresponding cleats from expansion modules, such as cleats 188 shown in FIG. 1E of expansion modules 110 and 111. Threaded bushings 192 then receive structural members, which pass through holes in the expansion modules to be received therein.

FIG. 1E illustrates an exploded perspective view of testing device 100 including I/O device 102, base module 106, and expansion modules 110 and 111, according to an example of the present disclosure. An optional screen cover 104 may be removably attached to the housing of I/O device 102 to provide protection to display 103. Base module 106 is removably connected to I/O device 102 by a plurality of connection members 150. According to an example, I/O device 102 includes a plurality of protrusions 174 that are configured to be received within through-holes 176 defined by the structural housing of base module 106. According to an example, first expansion module 110 has structure defining holes 178 and expansion module 111 has structure defining holes 180. Connection members 190 pass through holes 178 and 180 and are received within threaded bushings 192 of base module 106. Cleats 188 of expansion modules 110 and 111 are received within recesses 177 in the bottom of base module 106. First expansion module 110 includes expansion interface 184 to communicate power and control signals with base module 106. Likewise, expansion module 111 includes expansion interface 186 to communicate power and control signals.

FIG. 1F illustrates an exploded perspective view of testing device 100 including a removably connected module 194, according to an example of the present disclosure. Upon integration of first solution module 194, base module 106 provides electrical power and communication to first solution module 194 by base module backplane interface 170. Likewise, first solution module 194 provides electrical power and communication to I/O device 102 by way of top solution interface 196. First solution module 194 also includes a bottom solution interface (not shown) connectable to base module backplane interface 170, described in greater detail below. According to another example, a second solution module may be optionally disposed between first solution module 194 and base module 106. The base module backplane interface 170 connects power and communication (e.g., carrying data) busses of the base module 106 to modules connected to the base module 106 via base module backplane interface 170 or other interfaces.

First solution module 194 has a similar housing and form factor to base module 106 to provide integration between I/O device 102 and base module 106. First solution module 194 includes a plurality of through holes 198 to mate with corresponding protrusions 174 in the housing of I/O device 102. First solution module 194 provides electrical power and communication to I/O device 102 by way of top solution interface 196. First solution module 194 is removably connected to I/O device 102 by connection members 150.

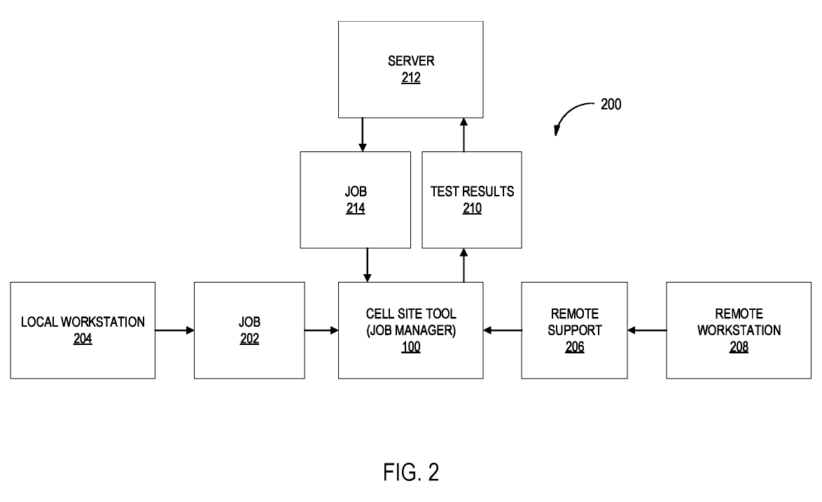

FIG. 2 illustrates test process automation workflow 200, according to an example of the present disclosure. A workstation, such as local workstation 204, creates a job, such as job 202, which may be loaded onto testing device 100. Alternatively, server 212 may load a job, such as job 214, onto testing device 100. Testing device 100 may receive remote support 206 from remote workstation 208.

Testing device 100 may deliver test results 210 to server 212. According to an example, testing device 100 may also deliver test results to local workstation 204 or remote workstation 208. Testing device 100 includes job manager software, known simply as job manager, which presents GUIs to manage jobs and execute tests. A job may include, among other things, a set of tests to be executed by testing device 100. The job manager can be used to define and customize jobs, and coordinates tasks and results across multiple testing devices and modules connected to testing device 100. The job manager displays step-by-step instructions to a user for executing tests with testing device 100. Job manager also displays progress and test results related to tests executed by testing device 100.

Testing device 100 supports communication with centralized management (CM) software running on server 212, which is presented to a user as a graphical user interface (GUI). The CM software organizes and pushes test configurations and job assignments 214 to testing device 100. The CM software automatically collects and organizes tests results 210 executed by testing device 100. The CM software presents a GUI on server 212, including a server dashboard of Key Performance Indicators (KPIs).

Testing device 100 may receive remote support 206, including communication and control, by remote workstation 208. Remote workstation 208 provides remote access and control of testing device 100, and also supports file transfer.

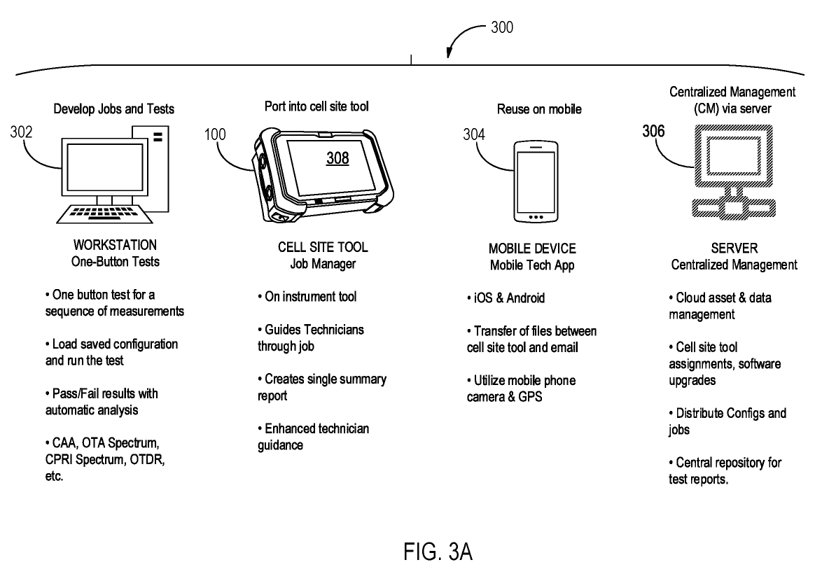

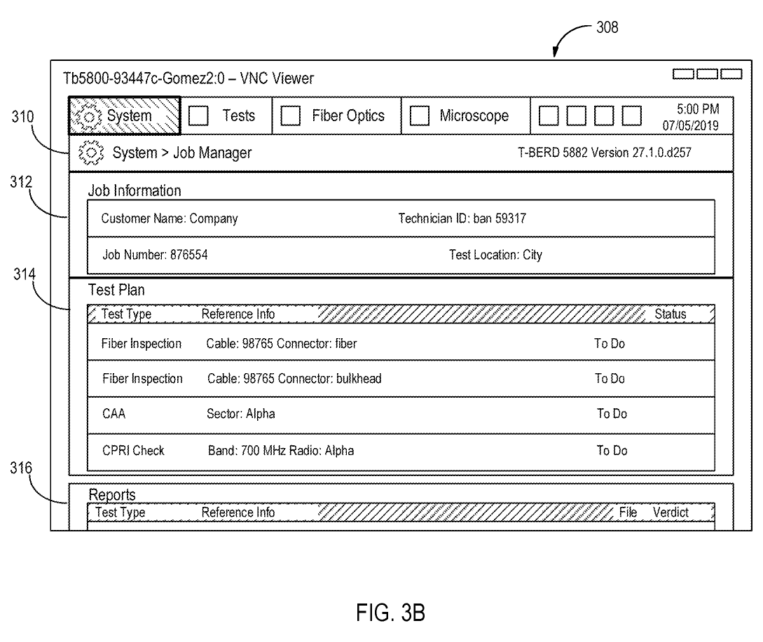

FIG. 3A illustrates a high level system diagram of test process automation 300, according to an example of the present disclosure. Test process automation 300 includes cooperation and communication between testing device 100, workstation 302, mobile device 304, and server 306. Workstation 302 is used to develop jobs, tests, and one-button tests. A one button test may be developed to execute a sequence of measurements by testing device 100. Workstation 302 may communicate with testing device 100 to load a saved configuration into testing device 100, and optionally control the testing device to run the test. Workstation 302 may develop a test with Pass/Fail results, and configure testing device 100 to perform automatic analysis. According to an example, workstation 302 may develop automated tests for CAA, OtA Spectrum, CPRI Spectrum, OTDR, etc.

Testing device 100 runs a job manager application, which may control the testing device 100 to perform the tests. The job manager application may guide technicians through a job, and create a single summary report corresponding to the executed job tests. According to an example, the job manager application also includes enhanced technician guidance, which may be selected by the technician to display step-by-step instructions on GUI 308 of testing device 100.

Mobile device 304 is a smart phone running an iOS or Android operating system and a mobile tech application. By using the mobile tech application on mobile device 304, a technician may communicate with server 306 and testing device 100 to transfer files such as a summary report corresponding to executed job tests. The mobile tech application may also be used to transfer files between testing device 100 and email. Mobile device 304 is a smart phone that includes a camera and GPS. A technician may control mobile device 304 to transfer GPS information and photographs to testing device 100 corresponding to a test. The job manager application on testing device 100 associates the GPS information and the photographs with a test, and stores the information in a corresponding summary report.

Server 306 runs centralized management software (CM) to provide centralized management of jobs executed by testing device 100, and other similarly configured testing devices. A service provider may manage thousands of similarly configured data centers and seek to ensure that all technicians servicing the data centers perform the same tests. According to an example, a service provider may deliver the same jobs, tests, and one button tests to testing devices in their fleet. According to an example, server 306 provides asset and data management, and delivers testing device assignments and software upgrades. Server 306 may distribute configurations and jobs to testing device 100, and serve as a central repository for test reports.

FIG. 3B illustrates a graphical user interface (GUI) 308 for testing device 100 having an automated test plan, according to an example of the present disclosure. Testing device 100 runs a job manager application, which is presented to a technician by job manager indication 310. According to an example, GUI 308 presents job manager 312, including customer name, job number, technician ID, and test location. According to an example, GUI 308 presents test plan 314, also known as a Job, indicating tests to be executed by testing device 100, and test status. According to the illustrated example, test plan 314 includes a fiber inspection test on cable 98765 for the fiber, a fiber inspection test on cable 98765 for the bulkhead, a CAA test at sector alpha, and a CPRI test at 700MHz for radio alpha. According to an example, GUI 308 presents reports 316 of tests that have been previously executed by testing device 100 for review and comment by a technician. For example, a technician may add GPS and photographs to a test indicated in Reports 316.

According to an example, a technician is able to determine certain parameters and configurations of the testing device. According to an alternate example, certain parameters and configurations of the testing device may be predetermined.

A testing device may provide an option to initialize configurations with the last saved settings and the option to initialize configurations from a saved user profile. A testing device may provide an option to initialize configurations to factory defaults.

A testing device may also provide the ability to generate a report that records the configurations used for an automated test instance and includes the results analysis with the option to include pass/fail determinations and screenshots. A testing device may also provide the ability to navigate through the steps of configuring the test as well as view the test results in an intuitive user experience. A testing device may also provide a progress bar / overall test status widget that is always visible to give the user an indication of how the test is proceeding in time. A testing device may also provide a task selection screen from which a technician may invoke the automated test and have the ability to see a snapshot of the status of tasks scheduled to run as well as a means of navigating quickly to each task result screen.

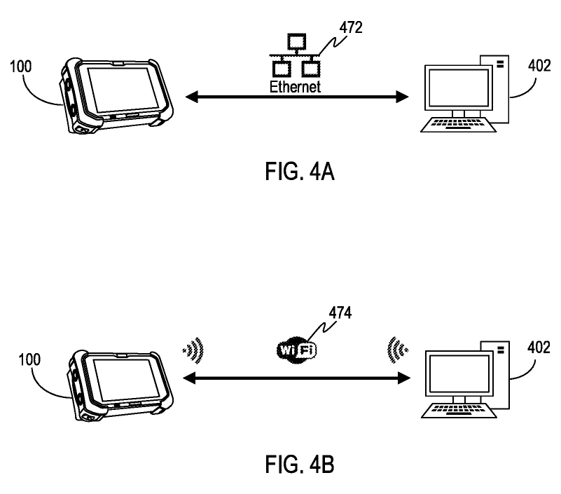

FIG. 4A illustrates a system diagram of testing device 100 connected to workstation 402 by an Ethernet connection 472 for remote access and control, according to an example of the present disclosure. Remote access allows permits viewing and control of I/O device 102 of testing device 100 from a remote location using workstation 402. In addition to configuring testing device 100 and performing tests, remote access permits file transfer to and from testing device 100 using the device’s file manager utility. A technician with remote access can rename and delete files, or create, rename, and delete directories. A remote access utility is downloaded and extracted onto workstation 402. Remote access may be established using a wired Ethernet connection 472.

According to an example, a remote access utility may also be launched on testing device 100 by interacting with a GUI via I/O device 102. The remote access connection is then automatically initiated. After a connection is established to the server, the device displays a message with a required code to access to the device remotely. To access device 100 from workstation 402, the code is input into the workstation utility to access device 100.

To test the connection between workstation 402 and testing device 100 the steps are: on workstation 402, launch the remote access utility. In the workstation utility, a test connection button is selected, and a connection test automatically launches. To display connection log details in real time, a full logs button is selected on the workstation. The connection log then appears, and provides the following information: upload and download speed from device to server; and latency between device and server. After analyzing the results, from the workstation: select a clear test results button to delete the current table, and retest the connection if desired. If the connection is deemed to be valid, the access code is then entered and a remote access connection is established.

FIG. 4B illustrates a system diagram of testing device 100 connected to workstation 402 by a wireless network (e.g., WiFi) connection 474 for remote access and control, according to an example of the present disclosure. According to the example, remote access may be established using wireless network connection 474 by enabling a wireless network module internal to base module 106.

A testing device (e.g. similar to the testing device 100 in FIG. 1A), as described herein, may provide features associated with finding interference in a RF environment. Indeed, in some examples, in addition to its other signal analysis features (e.g., spectrum analysis, etc.) a testing device may provide interference finding by analyzing RF power in an environment. Furthermore, the testing device may provide a visual display of RF power on a display of the testing device to indicate interference in the RF environment.

However, analyzing RF power to determine RF interference may, in some instances, come with difficulties. For example, an on-site technician operating a testing device may not necessarily be able to make adjustments to home in (i.e., focus) onto the RF interference and/or to troubleshoot when issues may arise with analyzing RF interference.

Furthermore, in many instances, identifying and analyzing RF interference may be a time-consuming process that may be difficult for on-site technicians to accomplish. Accordingly, it may be beneficial to provide improved RF interference finding that may be easily implementable.

Systems and methods described herein may be directed to, among other things, determining RF interference via implementation of a phased array antenna (PAA). In some examples, as described in further detail below, an RF interference finder as described herein may be implemented as one or more hardware and/or software elements (e.g., as a module) on a testing device (e.g., similar to the testing device 100).

In some examples, the RF interference finder may be configured to find a location and/or direction of RF interference in the field via implementation of the PAA. In some examples, the PAA may implement a narrow beam that may be angled and/or focused to enhance finding of RF inference. Moreover, in some examples, an RF interference finder may enable adjustments to the PAA to further focus and define aspects of the RF interference.

In some examples and as described in further detail below, the systems and methods described may, separately or in combination, implement a camera. In some examples, the camera may concurrently and/or synchronously “zoom” (e.g., in concert with the PAA) on to RF interference. In some examples, the video and/or image information captured by the camera may be displayed on a display (e.g., similar to the display 103), in combination with one or more visual representations of the RF interference.

In some examples, the RF interference finder may also include a component for determining distance to RF interference. In some instances, this component may be a combination of hardware and software elements, and may be referred to as a “range finder.”

So, in some examples, the systems and methods may implement the PAA to provide a RF scan and to determine RF interference. In some examples, this may include determining a location associated with the RF interference. In conjunction, the systems and methods may implement locational data and/or a range finder to particularly define a distance to the RF interference. Furthermore, a camera may be implemented to (visually) display and/or zoom into an area associated with the RF interference as well. Accordingly, the systems and methods provided herein may analyze various information, including RF information and image information, to determine and display aspects of RF interference, and to more effectively locate RF interference.

Often, it may be difficult to adjust typical RF antennas to focus in on to RF interference. For example, in the case of a typical RF antenna implemented to determine RF interference, information associated with the RF signals may flow (only) from the RF antenna to control elements (e.g., an FPGA). This information is typically not employed to make adjustments to the RF antenna to provide better RF interference analysis. However, as will be discussed in further detail below, the systems and methods described herein, by implementing a PAA, may enable information flow to be bi-directional between the PAA and control elements, thereby providing improved RF interference finding (e.g. via adjustments to the PAA).

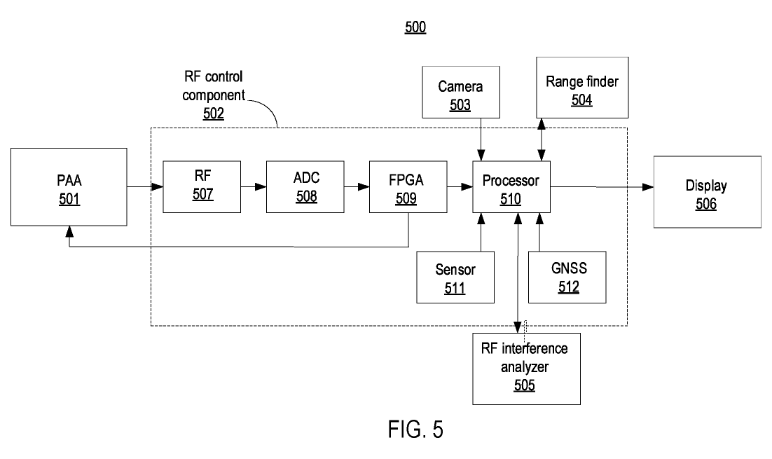

FIG. 5 illustrates a RF interference finder 500, according to examples of the present disclosure. In some examples, the RF interference finder 500 may be implemented as one or more hardware and/or software elements (e.g., as a module) on a testing device as described herein (e.g., similar to the testing device 100).

In some examples, the RF interference finder 500 may include a PAA 501. In some examples, the PAA 501 may include a plurality of antennas arranged to work in concert, where the plurality of antennas may provide steering of radio waves without requiring movement of the plurality of antennas themselves. Specifically, in some examples, the PAA 501 may enable shifting of a phase of a radio wave, thereby enabling a change in shape and direction of a radio wave pattern. In some instances, the plurality of antennas in the PAA 501 may be located to enable signals transmitted by individual antennas to be combined, and thereby providing better gain, directivity and performance.

In some examples, the PAA 501 may provide a narrow beam that may be angled and/or focused to enhance finding of RF interference. In particular, in some examples, by transmitting signals having a same frequency but having a (e.g., calculated) phase difference between each of the plurality of antennas in the array, the PAA 501 may achieve better directivity than other antennas (e.g., a directional antenna).

In some examples, the plurality of antennas of the PAA 501 may be provided in paneled layout. Furthermore, in some examples, each the plurality of antennas may be rectangular in shape, and in other examples, each of the plurality of antennas may be square in shape. So, in some examples, the PAA may be configured to selectively implement a one by one (1x1), two by two (2x2), three by three (3x3), four by four (4x4) paneled antenna layout, among other configurations. In this manner, by controlling a number of antenna elements being implemented as needed, the PAA can 501 may progressively home in on to and enable analysis of RF interference.

In some examples, the RF interference finder 500 may also include a camera 503. In some examples, and as will be described in further detail below, the camera 503 may be implemented to provide a visual representation of an area where RF interference may be located. In particular, in some examples, the camera 503 may capture image information from a location that the PAA 501 may be directed at. Also, in some examples, the image information may be provided to the processor 510, and may be displayed on the display 506.

In some examples, and as will described in further detail below, the camera 503 may be synchronized to focus and defocus with the PAA 501. That is, in some examples, various data associated with RF interference, such as data analyzed by an RF interference analyzer, may be utilized to adjust (e.g., focus) the camera to display an area associated with the RF interference. In particular, in some examples, the camera 503 may provide a “zoom” function to focus into to the RF interference. Moreover, in some examples, the camera 503 may concurrently and/or synchronously focus into a captured portion of image data based on RF information received and analyzed.

In some examples, the RF interference finder 500 may also include a range finder 504. In some examples, the range finder 504 may include hardware and/or software components directed to determining a distance to a particular location. In particular, in some examples, the range finder 504 may be configured to determine a distance to a location having RF interference. In some examples, the range finder 504 may implement a laser to determine distance.

In some examples, the RF interference finder 500 may include a RF interference analyzer 505. In some examples, the RF interference analyzer 505 may include hardware and/or software components directed to finding RF interference. In particular, in some examples, the RF interference analyzer 505 may implement, among other things, a spectrum analyzer functionality that may be similar to the spectrum analysis functionalities described above with respect to the test device 100. To determine RF interference, in some examples, the RF interference analyzer 505 may analyze (and/or display) frequency with respect to amplitude of RF signals (i.e., RF signal power), which may enable determining of a type and frequency of an interfering signal.

In some examples, the RF interference finder 500 may include a display 506. In some examples, and as will discussed in further detail below, the display 506 may be utilized to, among other things, display various technical data associated with RF interference, display a visual representation of an area having RF interference, and enable a “zoomed” visual representation of the area having RF interference as well.

In some examples, the RF interference finder 500 may include a RF control component 502. In some examples, the RF control component 502 may include, among other things, an RF receiver 507, an analog-to-digital convertor (ADC) 508, and a field-programmable gate array (FPGA) 509, a processor 510, a sensor 511, and global navigation satellite system (GNSS) component 512.

In some examples, the PAA 501 may receive an RF signal, and may provide the RF signal to the RF receiver 507. The RF receiver 507 may couple the RF signal to the ADC 508 for conversion. In some examples, the converted RF signal may be provided to the FPGA 509, which may further provide digital data associated with the converted RF signal to the processor 510.

In some examples, the (converted) RF signal may be provided to the RF interference analyzer 505. In particular, in some examples, the RF interference analyzer 505 may analyze data associated with the RF signal to determine RF interference. Information that may be determined via the analysis may include, among other things, an amount of RF interference, a type of RF interference, and a direction of RF interference. In addition, information associated with the RF interference (e.g., as provided by the RF interference analyzer 505) may displayed on the display 506 as well.

In some examples, based on analysis of the RF interference analyzer 505, the PAA 501 may implement a narrow (or narrower) beam that may be angled and/or focused (or defocused) to enhance finding of RF inference. In some examples, in concert with the focusing or defocusing of the PAA 501, the camera 503 may be concurrently and/or synchronously focused or defocused (visually) to display the location associated with the RF interference as well.

In some examples, the sensor 511 and/or the GNSS component 512 may be implemented to determine a location associated with the RF interference finder 500 and/or associated testing device. In some examples, the sensor 511 may be a nine (9)-axis sensor, and may include a 3-axis accelerometer, a 3-axis gyroscope, and a 3-axis magnetometer. In some examples, the GNSS component 512 may receive and provide global positioning system (GPS) data associated with the RF interference finder 500. So, in some examples, in combination with the range finder 504, the sensor 511 and/or the GNSS component 512 may determine a location and/or a distance from a testing device to a location associated with RF interference. The GPS coordinates of RF interference may be determined using the GPS coordinates of the RF interference finder 500, the distance information from the range finder 504 and the azimuth information from the nine (9)-axis sensor.

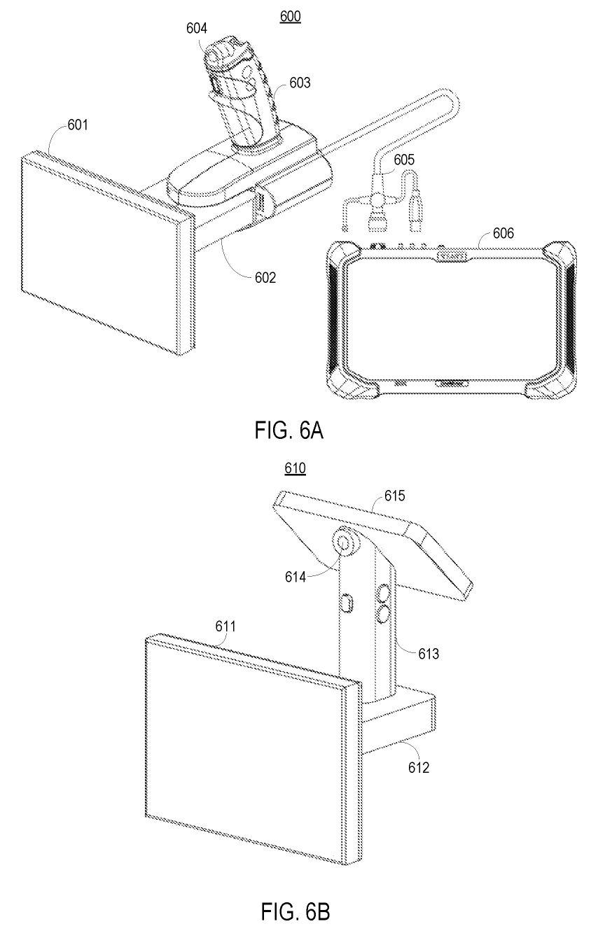

FIGS. 6A-6B illustrate testing apparatuses with RF interference capabilities, according to examples of the present disclosure. In particular, FIG. 6A illustrates a non-mounted version of a testing apparatus 600, and FIG. 6B illustrates a mounted version of a testing apparatus 610.

In FIG. 6A, the testing apparatus 600 may include a PAA 601 (e.g., similar to the PAA 501), a support structure 602, and a handle 603. In some examples, a user may utilize the handle 603 to direct the PAA 601 in a direction towards an RF signal. Also, in some examples, the handle 603 may include a camera 604 (e.g., similar to the camera 503).

In some examples, a connector 605 may be utilized to electrically couple the support structure 602 to the testing device 606 (e.g. similar to the testing device 100). In some examples, the testing device 606 may include an RF control component (e.g., similar to the RF control component 502), and may provide RF interference finding capabilities as described herein.

In FIG. 6B, the testing apparatus 610 may include a PAA 611 (e.g., similar to the PAA 501), a support structure 612, and a handle 613. In some examples, the handle 603 may include a camera 614 (e.g., similar to the camera 503). In some examples, a testing device 615 may be directly mounted to the support structure 602. In some examples, the testing device 615 may include an RF control component, and may provide RF interference finding capabilities as described herein.

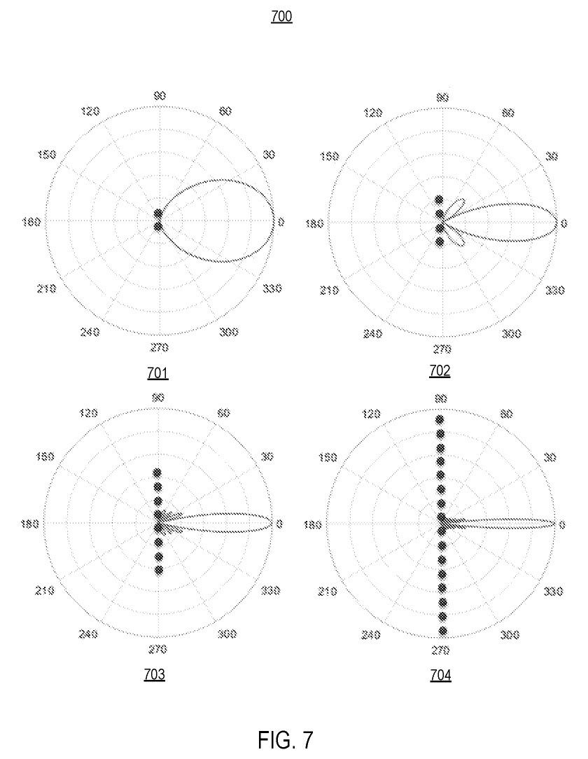

FIG. 7 illustrates a plurality of charts 700 indicating RF interference for a PAA, according to examples of the present disclosure. A first chart 701 indicates an RF interference result based on use of a two by one (2x1) array of the PAA. A second chart 702 indicates an RF interference result based on use of a four by one (4x1) array of the PAA. A third chart 703 indicates an RF interference result based on use of a eight by one (8x1) array of the PAA. A fourth chart 704 indicates an RF interference result based on use of a sixteen by one (16x1) array of the PAA.

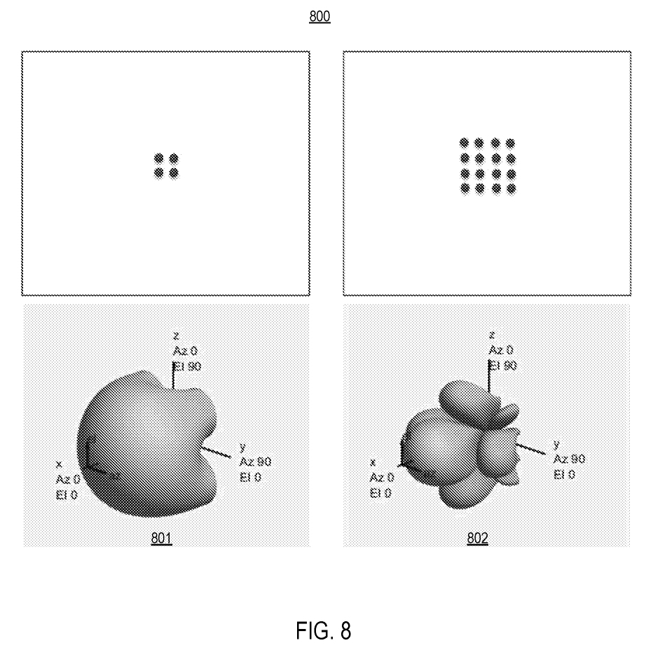

FIG. 8 illustrates a plurality of charts 800 indicating RF interference for a PAA, according to examples of the present disclosure. A first chart 801 indicates an RF interference result based on use of a two by two (2x2) array of the PAA. A second chart 802 indicates an RF interference result based on use of a four by four (4x4) array of the PAA.

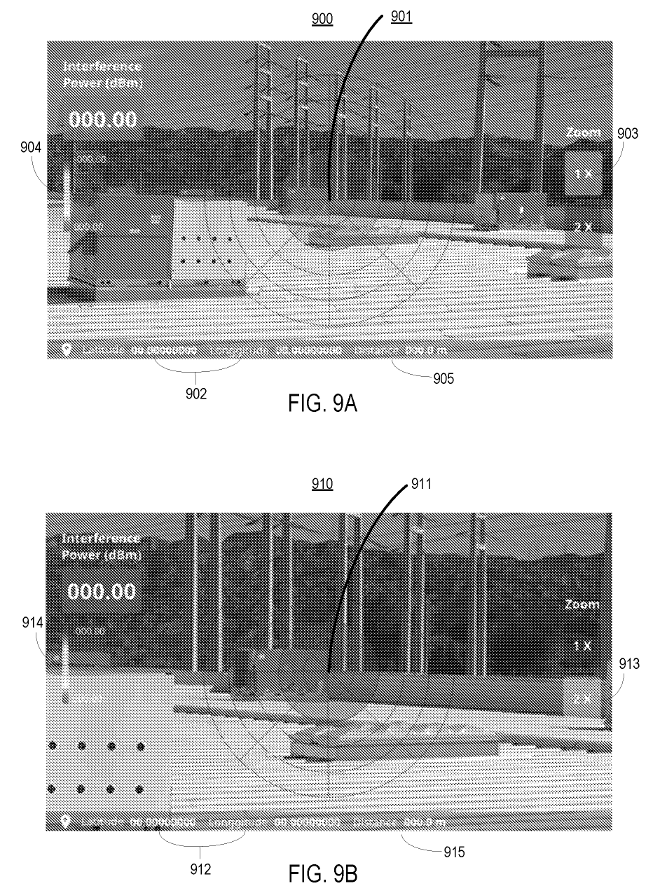

FIGS. 9A-9B illustrate images provided by a camera of a (e.g., similar to the camera 503) of an RF interference finder (e.g., similar to the RF interference finder 500), according to examples of the present disclosure. In some examples, a first image 900 and a second image 910 may be captured by a camera (e.g., similar to the camera 503) of an RF interference finder (e.g., similar to the RF interference finder 500).

In FIG. 9A, the first image 900 may include a RF interference location 901, a geographic location 902 of an associated testing device (e.g., similar to the testing device 100), a zoom indicator 903, an RF interference indicator 904, and a distance indicator 905. In some examples, the geographic location 902 may be provided by a latitude and longitude of the location. Also, as indicated in FIG. 9A, the zoom indicator may vary between 1x (e.g., no zoom) and 2x (e.g., a predetermined zoom amount). Other zoom configurations may be provided as well.

In some examples, the RF interference indicator 904 may indicate a (determined) level of RF interference, as may be determined by an RF interference analyzer (e.g., the RF interference analyzer 505). In some examples, the distance indicator 905 may indicate a determined and/or approximate distance to a location having RF interference. In some examples, the distance to the location having RF interference may be determined by a range finder (e.g., such as the range finder 504).

FIG. 9B illustrates the second image 910, where the second image 910 may be a zoomed version of the first image 900. In FIG. 9B, a second image 910 may include a RF interference location 911, a geographic location 912 of an associated testing device, a zoom indicator 913, an RF interference indicator 914, and a distance indicator 915. In some examples, upon providing a zoomed view, the zoom indicator 913 may indicate “2x”. In some examples and as described above, the zoom feature provided by the camera may be synchronized to zoom in and zoom out with a focusing and defocusing of a PAA (e.g., similar to the PAA 501).

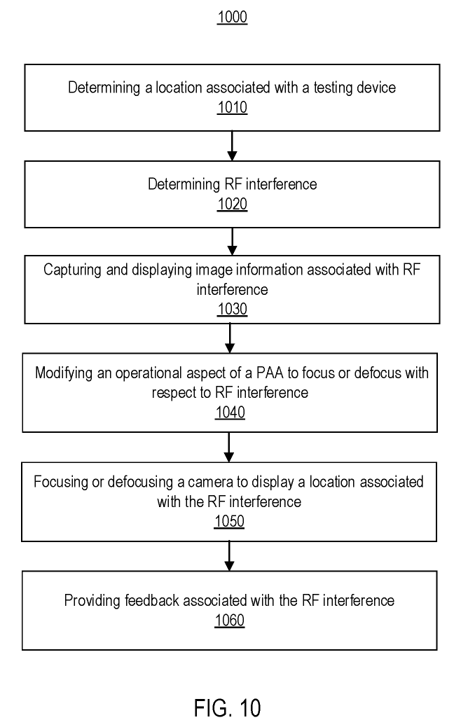

FIG. 10 illustrates a method for determining RF interference utilizing a phased array antenna (PAA), according to examples of the present disclosure. The method 1000 is provided by way of example, as there may be a variety of ways to carry out the method described herein. Each block shown in FIG. 10 may further represent one or more processes, methods, or subroutines, and one or more of the blocks may include machine-readable instructions stored on a non-transitory computer-readable medium and executed by a processor or other type of processing circuit to perform one or more operations described herein.

In some examples, the method 1000 may be executed or otherwise performed by other systems, or a combination of systems. Furthermore, in some examples, the systems and methods described herein may include a testing device for testing conditions associated with RF communications, comprising an input/output (I/O) device comprising a display, a processor, a memory to store machine readable instructions executable by the processor.

Reference is now made with respect to FIG. 10. At 1010, the method may include determining a location associated with a testing device implementing a PAA. In some examples, the testing device may include one or more of a nine (9) axis sensor and global navigation satellite system (GNSS) component that may enable determining of the location.

At 1020, the method may include determining RF interference associated with a testing device. Specifically, in some examples, the method may implement a PAA (e.g., similar to the PAA 501) and an RF interference finder (e.g., similar to the RF interference analyzer 505) of a testing device to receive and analyze RF signals and to determine RF interference.

At 1030, the method may include capturing and displaying image information associated with RF interference. In some examples, upon determining the RF interference, a camera (e.g., similar to the camera 503) may capture image information associated with the RF interference, and may enable display of the image information on a display (e.g., similar to the display 506).

At 1040, the method may include modifying an operational aspect of a PAA to focus or defocus with respect to RF interference. So, in some examples, upon analyzing aspects of the RF interference (e.g., direction, amount of the RF interference), this may include increasing a number of the antenna employed on the PAA. In particular, an FPGA (e.g., similar to the FPGA 509) may control aspects of the PAA, including increasing a number of active antennas deployed on the PAA (e.g., from two by two (2x2) to three by three (3x3). In so doing, in some examples, the testing device may be able to (further) home in on to the detected RF interference. In particular, in some examples, based on analysis of the RF interference finder, the PAA may implement a narrow (or narrower) beam that may be angled and/or focused (or defocused) to enhance finding of RF inference.

At 1050, in some examples, upon focusing in onto RF interference (e.g., at 1040), the method may include focusing or defocusing the camera to display a location associated with RF interference. In particular, in some examples, the method (at 1050) may include concurrently and/or synchronously zoom in or zoom out the camera display the location associated with the RF interference as well.

At 1060, in some examples, the method may include providing feedback associated with the RF interference on a display of a testing device. In some examples, this may include providing a recommendation and/or determination (e.g., a calculation) with respect to a RF interference.

In some examples, the systems and methods described herein may include a testing device for testing conditions with radio frequency (RF) interference, comprising a processor, a memory to store machine readable instructions executable by the processor to perform data center testing, an input/output (I/O) device comprising a camera, a display, a phased array antenna (PAA), and an RF control component, wherein the RF control component is to focus reception of the PAA according to analyzed RF interference, adjust a viewing of the camera synchronously with focusing reception of the PAA, and display RF interference information associated with an image captured by the camera. In some examples, the RF control component includes an RF receiver, an analog-to-digital convertor (ADC), a field-programmable gate array (FPGA), a processor, a sensor, and global navigation satellite system (GNSS) component, the sensor is a nine (9)-axis sensor, and the GNSS component is to utilize global positioning system (GPS) data. In some examples, the systems and methods may further include an interference analyzer to analyze data associated with RF signals to determine the RF interference and a range finder to determine a distance to a location associated with the RF interference. In some examples, the PAA is be configured to selectively implement a one by one (1x1), two by two (2x2), three by three (3x3), four by four (4x4) paneled antenna layout, and the FPGA is to provide direct the PAA to selectively implement a particular paneled antenna layout.

In some examples, the systems and methods described herein may include a method for implementing a testing device with a single output port, the method comprising determining a location associated with a testing device implementing a PAA of a testing device, determining RF interference associated with the testing device, capturing and displaying image information associated with the RF interference, modifying an operational aspect of a PAA to focus with respect to the RF interference, focusing a camera of the testing device to display a location associated with the RF interference based on the modifying of the operational aspect of the PAA, and displaying feedback associated with the RF interference on a display of the testing device. In some examples, the methods may further include determining a distance to the RF interference, determining a location of the testing device, and analyzing data associated with received RF signals to determine the RF interference. In some examples, the PAA is be configured to selectively implement a one by one (1x1), two by two (2x2), three by three (3x3), four by four (4x4) paneled antenna layout, and the methods may include directing the PAA to selectively implement a particular paneled antenna layout.

In some examples, the systems and methods may include an RF interference finder, comprising a camera, a display, a phased array antenna (PAA), an interference analyzer to analyze data associated with RF signals to determine the RF interference, a range finder to determine a distance to a location associated with the RF interference, and an RF control component, the RF control component including an RF receiver, an analog-to-digital convertor (ADC), a field-programmable gate array (FPGA), a processor, a sensor, and a global navigation satellite system (GNSS) component. In some examples, the RF control component is to focus and defocus reception of the PAA according to analyzed RF interference and adjust a viewing of the camera synchronously with the focusing and defocusing reception of the PAA, and the PAA is be configured to selectively implement a one by one (1x1), two by two (2x2), three by three (3x3), four by four (4x4) paneled antenna layout. Also, in some examples, the FPGA is to provide direct the PAA to selectively implement a particular paneled antenna layout, the GNSS component is to utilize global positioning system (GPS) data, and the sensor is a nine (9)-axis sensor.

What has been described and illustrated herein are examples of the disclosure along with some variations. The terms, descriptions, and figures used herein are set forth by way of illustration only and are not meant as limitations. Many variations are possible within the scope of the disclosure, which is intended to be defined by the following claims–and their equivalents–in which all terms are meant in their broadest reasonable sense unless otherwise indicated.

1. A testing device for testing conditions with radio frequency (RF) interference, comprising:
a processor;
a memory to store machine readable instructions executable by the processor to perform data center testing;
an input/output (I/O) device comprising:
a camera;
a display;
a phased array antenna (PAA); and
an RF control component, wherein the RF control component is to:
focus reception of the PAA according to analyzed RF interference;
adjust a viewing of the camera synchronously with the focusing reception of the PAA; and
display RF interference information on an image captured by the camera.

2. The testing device according to claim 1, wherein the RF control component includes an RF receiver, an analog-to-digital convertor (ADC), a field-programmable gate array (FPGA), a processor, a sensor, and global navigation satellite system (GNSS) component.

3. The testing device according to claim 2, wherein the sensor is a nine (9)-axis sensor.

4. The testing device according to claim 2, wherein the GNSS component is to utilize global positioning system (GPS) data.

5. The testing device according to claim 1, further comprising an interference analyzer to analyze data associated with RF signals to determine the RF interference.

6. The testing device according to claim 1, further comprising a range finder to determine a distance to a location associated with the RF interference.

7. The testing device according to claim 2, wherein the PAA is be configured to selectively implement a one by one (1x1), two by two (2x2), three by three (3x3), four by four (4x4) paneled antenna layout.

8. The testing device according to claim 7, wherein the FPGA is to provide direct the PAA to selectively implement a particular paneled antenna layout.

9. A method for implementing a testing device with a single output port, the method comprising:
determining a location associated with a testing device implementing a PAA of a testing device;
determining RF interference associated with the testing device;
capturing and displaying image information associated with the RF interference;
modifying an operational aspect of a PAA to focus with respect to the RF interference;
focusing a camera of the testing device to display a location associated with the RF interference based on the modifying of the operational aspect of the PAA; and
displaying feedback associated with the RF interference on a display of the testing device.

10. The method of claim 9, further comprising determining a distance to the RF interference.

11. The method of claim 9, further comprising determining a location of the testing device.

12. The method of claim 9, further comprising analyzing data associated with received RF signals to determine the RF interference.

13. The method of claim 9, wherein the PAA is be configured to selectively implement a one by one (1x1), two by two (2x2), three by three (3x3), four by four (4x4) paneled antenna layout.

14. The method of claim 13, directing the PAA to selectively implement a particular paneled antenna layout.

15. An RF interference finder, comprising:
a camera;
a display;
a phased array antenna (PAA);
an interference analyzer to analyze data associated with RF signals to determine the RF interference;
a range finder to determine a distance to a location associated with the RF interference; and
an RF control component, the RF control component including:
an RF receiver;
an analog-to-digital convertor (ADC);
a field-programmable gate array (FPGA);
a processor;
a sensor; and
a global navigation satellite system (GNSS) component.

16. The RF interference finder of claim 15, wherein the RF control component is to focus and defocus reception of the PAA according to analyzed RF interference and adjust a viewing of the camera synchronously with the focusing and defocusing reception of the PAA.

17. The RF interference finder of claim 15, wherein the PAA is be configured to selectively implement a one by one (1x1), two by two (2x2), three by three (3x3), four by four (4x4) paneled antenna layout.

18. The RF interference finder of claim 17, wherein the FPGA is to provide direct the PAA to selectively implement a particular paneled antenna layout.

19. The RF interference finder of claim 18, wherein the GNSS component is to utilize global positioning system (GPS) data.

20. The RF interference finder of claim 18, wherein the sensor is a nine (9)-axis sensor.
